(19) United States
(12) Patent Application Publication
(10) Pub. No.: US 2005/0068729 A1
(43) Pub. Date: Mar. 31, 2005

(54) Dual-fan heat dissipator

(76) Inventor: Jen Cheng Lin, Taipei Hsien (JP)

Correspondence Address: BACON & THOMAS, PLLC, 625 SLATERS LANE, FOURTH FLOOR, ALEXANDRIA, VA, 22314, US

(21) Appl. No.: 10/669,368

(22) Filed: Sep. 25, 2003

(51) Int. Cl. H05K 7/20

(52) U.S. Cl. 361/695

(57) ABSTRACT

A dual fan heat dissipator includes a top casing, a middle casing and a bottom casing together form a hollow cylindrical passage for airflow generated by two fans co-axially connected to each other and securely received in the cylindrical passage. The heat dissipator is able to generate effective airflow and air pressure to an object to dissipate the heat generated by the object.

### BACKGROUND OF THE INVENTION

1. Field of the Invention

The present invention relates to a heat dissipator, and more particularly to heat dissipator with two fans coaxially connected together to increase the wind pressure applied onto a heat source so as to dissipate the heat quickly.

2. Description of Related Art

A conventional heat dissipator includes a fan and multiple heat dissipating fins mounted under the fan. When the central processing unit (CPU) is running and heat is thus generated, the heat is conducted to the heat dissipating fins. Then the fan is able to dissipate the heat by the air flow generated by the fan. Due to the higher and higher CPU speed requirements, the heat generating rate is increasingly accelerated.

In order to cope with the heat increase, manufacturers strive to improve the existing heat dissipator to achieve better heat dissipation efficiency. The improvements comprise the modification of the a heat dissipating fin structure by defining channels between two adjacent rows of fins to increase the air circulation and the alterations of the fan type to have more output power so that the air flow generated by the fan is stronger than ever. However, the improvements are modifications to the present already existing structure, none of which can really cope with the rapid growth rate of the heat resulting from the higher and higher CPU resolution speed.

To overcome the shortcomings, the present invention tends to provide an improved heat dissipator to mitigate the aforementioned problems.

### SUMMARY OF THE INVENTION

The primary objective of the present invention is to provide an improved heat dissipator having two coaxial fans so that the wind pressure applied on an object is increased and thus the heat dissipation is effective.

Other objects, advantages and novel features of the invention will become more apparent from the following detailed description when taken in conjunction with the accompanying drawings.

### BRIEF DESCRIPTION OF THE DRAWINGS

FIG. 1 is an exploded perspective view of the dual-fan heat dissipator of the present invention;

FIG. 2 is a perspective view of the assembled heat dissipator of the present invention;

FIG. 3 is a schematic diagram showing the comparison of two fans with different dimensions; and

FIG. 4 is a schematic diagram showing the performance of two fans connected to each other in series.

### DETAILED DESCRIPTION OF THE PREFERRED EMBODIMENT

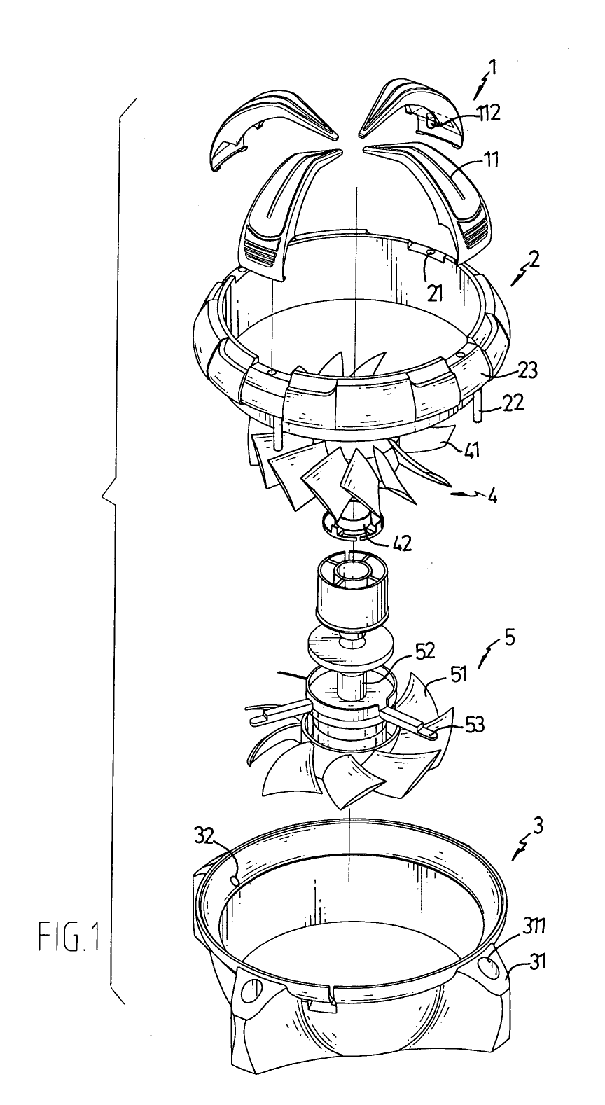

With reference to FIG. 1, the dual-fan heat dissipator in accordance with the present invention includes a top casing (1), a middle casing (2), a bottom casing (3), a first fan (4) and a second fan (5).

The top casing (1) is composed of multiple equally spaced legs (11) extending upward. Each leg (11) has a first pin (112) extending out from from a bottom of the leg (11).

The middle casing (2) is also a ring and has multiple holes (21) defined in a recessed area (23) to receive therein a corresponding one of the first pins (112) of the legs (11) of the top casing (1) and multiple second pins (22) extending out in a direction the same as that of the first pins (121).

The bottom casing (3) is a ring and has multiple assembly blocks (31) formed on an outer periphery of the bottom casing (3) and each assembly block (31) having a positioning hole (311) defined therethrough and multiple assembly holes (32) each defined between a joint between the assembly block (31) and the outer periphery of the bottom casing (3) to correspond to one of the second pins (22).

The first fan (4) has a first fan blade assembly (41) and a first shaft (42) connected to the first fan blade assembly (41).

The second fan (5) has a second fan blade assembly (51), a second shaft (52) connected to the second fan blade assembly (51) and multiple arms (53) divergently extending out from the second shaft (52).

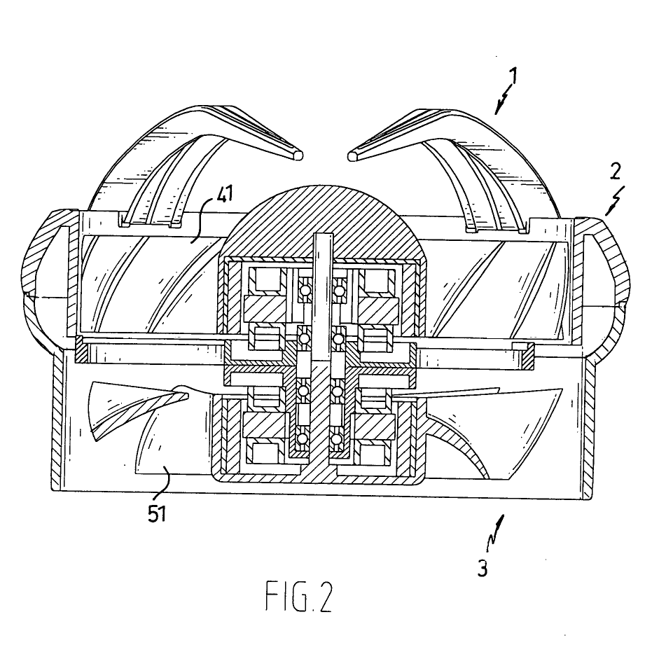

With reference to FIG. 2, when the dual-fan heat dissipator of the present invention is in assembly, the first pins (112) are inserted into the corresponding holes (21) of the middle casing (2) to combine the first casing (1) and the second casing (2). Then the second pins (22) are inserted into the corresponding assembly holes (32) of the bottom casing (3) to combine the combination of the top casing (1) and the middle casing (2) with the bottom casing (3). Due to the provision of the recessed areas (23) in the middle casing (2), after the first pins (112) are inserted into the corresponding holes (21) of the middle casing (21), the outer surface of the legs (11) are flush with the outer surface of the middle casing (2).

Thereafter, the first shaft (42) is securely connected to the second shaft (52) to secure engagement between the first fan (4) and the second fan (5). Preferably, the first shaft (42) and the second shaft (52) are integrally formed so that the first fan (4) is coaxial with the second fan (5). Then the arms (53) are securely connected to an inner periphery of the bottom casing (3) to support and position the location of the fan assembly inside the casing assembly, which completes the assembly of the present invention.

After the assembly of the heat dissipator of the present invention, the combination of the top, middle and bottom casing (1,2,3) forms a cylindrical pipe-like structure, which helps to concentrate the wind flowing through the casing assembly.

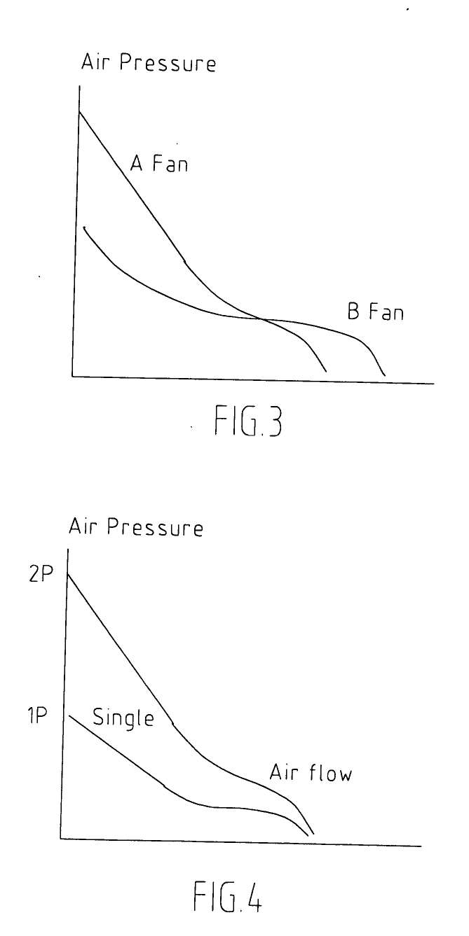

With reference to FIG. 3, it is noted that two fans (A,B) with different dimensions are measured and the performances are respectively recorded to compare with each other. It is learned from the chart that under a fixed air pressure generated from the respective fan (A,B), fan (A) has a larger air flow than that of fan (B) until a critical point. Again, under a fixed air flow, the air pressure performance of fan (A) has a larger air pressure than that of fan (B) until the critical point. That is, the conclusion is that the smaller the fan dimension is, the bigger the air flow and air pressure are for the smaller fan, which is true until the critical point.

With reference to FIG. 4, when the two fans (A,B) are combined in series, the same as that of the present invention, the performances in both air pressure and air flow are multiples of the performance of a single fan, which proves that when two fans are combined coaxially, the performance will be much more effective when compared with a single fan.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

1. A heat dissipator comprising:
a top casing being a ring and having multiple equally spaced legs extending upward and each leg having a first pin extending out from a bottom of the leg;
a middle casing being a ring and having multiple holes defined to receive therein a corresponding one of the first pins of the top casing and multiple second pins extending out in a direction the same as that of the first pins;
a bottom casing being a ring and having multiple assembly blocks formed on an outer periphery of the bottom casing and each assembly block having a positioning hole defined therethrough and multiple assembly holes each defined between a joint between the assembly block and the outer periphery of the bottom casing to correspond to and receive therein the second pins;
a first fan received in a combination of the top, middle and bottom casings and having a first fan blade assembly and a first shaft connected to the first fan blade assembly; and
a second fan having a second fan blade assembly, a second shaft securely connected to the second fan blade assembly and the first shaft and multiple arms divergently extending out from the second shaft to securely engage with an inner periphery of the bottom casing so as to position a combination of the first fan and the second fan inside the combination of the top, middle and bottom casings, whereby the combination of the first fan and the second fan is able to increase the air pressure and air flow to increase heat dissipation efficiency.

2. The heat dissipator as claimed in claim 1, wherein the middle casing has recessed areas and the holes are respectively defined in a bottom surface of the recessed area so that after the first pin of one of the legs are inserted into the holes, an outer surface of the leg is flush with an outer surface of the middle casing.
